(19) United States
(12) Patent Application Publication
(10) Pub. No.: US 2026/0180559 A1
(43) Pub. Date: Jun. 25, 2026

(54) SCANNABLE FLIP-FLOP

(71) Applicant: SAMSUNG ELECTRONICS CO., LTD., Suwon-si (KR)

(72) Inventor: Minsu KIM, Suwon-si (KR)

(73) Assignee: SAMSUNG ELECTRONICS CO., LTD., Suwon-si (KR)

(21) Appl. No.: 19/428,691

(22) Filed: Dec. 22, 2025

(30) Foreign Application Priority Data
Dec. 24, 2024 (KR) 10-2024-0195371

(51) Int. Cl. H03K 3/037; H03K 19/20

(52) U.S. Cl. CPC H03K 3/0372; H03K 19/20

(57) ABSTRACT

A flip-flop includes a pulse generation circuit, a dynamic stage circuit, and a static stage circuit. The pulse generation circuit is configured to output a delayed clock signal, and output a pulse signal that is delay-synchronized with a rising edge of a clock signal based on the clock signal, an inverted scan input signal, and a scan enable signal. The dynamic stage circuit includes a first P-type transistor configured to precharge a first node, a first N-type transistor coupled with the first node and a second node, a second N-type transistor coupled in parallel with the first N-type transistor, and a third N-type transistor coupled with the second node. The static stage circuit is configured to, based on the clock signal, invert a voltage at the first node and provide the inverted voltage as output data, or maintain a state of the output data.

### CROSS-REFERENCE TO RELATED APPLICATIONS

This application claims priority under 35 U.S.C. § 119 to Korean Patent Application No. 10-2024-0195371, filed on Dec. 24, 2024, in the Korean Intellectual Property Office, the disclosure of which is incorporated by reference herein in its entirety.

### BACKGROUND

The present disclosure relates generally to flip-flops, and more particularly, to a scannable flip-flop.

Design for testability (DFT) technology, which may be used to test semiconductor chips, may be widely employed to ensure chip quality. Examples of DFT technologies may include, but not be limited to, a scan test technology that may include connecting internal flip-flops of a circuit to a scan chain in order to apply scan input signals for testing and/or to read values corresponding to the scan input signals.

A flip-flop may store and/or sequentially transfer input data based on a clock signal and/or a pulse signal. A scannable flip-flop may refer to a flip-flop that may be used for scan testing, and thereby, may need a multiplexing function for signals associated with the scan test.

### SUMMARY

One or more example embodiments of the present disclosure provide a scannable flip-flop providing a scan multiplexing function while reducing a delay, when compared to related flip-flops.

According to an aspect of the present disclosure, a flip-flop includes a pulse generation circuit, a dynamic stage circuit, and a static stage circuit. The pulse generation circuit is configured to output a delayed clock signal, and output a pulse signal that is delay-synchronized with a rising edge of a clock signal based on the clock signal, an inverted scan input signal, and a scan enable signal. The scan enable signal indicates activation of a scan mode. The dynamic stage circuit includes a first P-type transistor configured to precharge a first node based on the delayed clock signal, a first N-type transistor coupled with the first node and a second node and configured to turn on based on input data, a second N-type transistor coupled in parallel with the first N-type transistor and configured to turn on based on the scan enable signal, and a third N-type transistor coupled with the second node and configured to discharge the first node based on the pulse signal. The static stage circuit is configured to, based on the clock signal being a first logic level, invert a voltage at the first node and provide the inverted voltage as output data and, based on the clock signal being a second logic level, maintain a state of the output data.

According to an aspect of the present disclosure, a flip-flop includes a pulse generation circuit, a dynamic stage circuit, and static stage circuit. The pulse generation circuit is configured to output a delayed clock signal, and output a pulse signal that is delay-synchronized with a rising edge of a clock signal based on the clock signal, an inverted scan input signal, and a scan enable signal. The scan enable signal indicates activation of a scan mode. The dynamic stage circuit is configured to output an internal signal, transition the internal signal to a logic high level based on the delayed clock signal, and transition the internal signal to a logic low level based on at least one of input data, the scan enable signal, or the pulse signal. The static stage circuit is configured to, based on the clock signal being a first logic level, invert a voltage at a first node and provide the inverted voltage as output data and, based on the clock signal being a second logic level, maintain a state of the output data.

According to an aspect of the present disclosure, a flip-flop includes a pulse generation circuit, a dynamic stage circuit, and a static stage circuit. The pulse generation circuit is configured to output a delayed clock signal, and output a pulse signal that is delay-synchronized with a rising edge of a clock signal based on the clock signal, an inverted scan input signal, and a scan enable signal. The scan enable signal indicates activation of a scan mode. The dynamic stage circuit includes a first P-type transistor configured to precharge a first node based on the delayed clock signal, a path formation circuit coupled with the first node and a second node and configured to provide a path between the first node and the second node based on at least one of input data or the scan enable signal, and a first N-type transistor coupled with the second node and configured to discharge the first node based on the pulse signal. The static stage circuit is configured to, based on the clock signal being a first logic level, invert a voltage at the first node and provide the inverted voltage as output data and, based on the clock signal being a second logic level, maintain a state of the output data.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 is a block diagram of a scannable flip-flop, according to one or more embodiments;

FIG. 2 is a circuit diagram of a pulse generation circuit, according to one or more embodiments;

FIG. 3 is a circuit diagram of a dynamic stage circuit, according to one or more embodiments;

FIG. 4 is a circuit diagram of a keeper circuit, according to one or more embodiments;

FIG. 5 is a circuit diagram of a static stage circuit, according to one or more embodiments;

FIG. 6 is a circuit diagram illustrating a combination of the dynamic stage circuit of FIG. 3 and the static stage circuit of FIG. 5.

FIG. 7 is a circuit diagram of a dynamic stage circuit implementing a logic wide-OR circuit, according to one or more embodiments;

FIG. 8 is a circuit diagram of a dynamic stage circuit implementing a logic wide-OR circuit and a logic AND circuit, according to one or more embodiments;

FIG. 9 is a circuit diagram of a dynamic stage circuit implementing a logic wide-OR circuit and a logic AND circuit, according to one or more embodiments;

FIG. 10 is a circuit diagram of a scannable flip-flop including a clocked domino circuit, according to one or more embodiments; and

FIG. 11 is a circuit diagram of the clocked domino circuit of FIG. 10, according to one or more embodiments.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

In the present disclosure, the articles “a” and “an” are intended to include one or more items, and may be used interchangeably with “one or more.” Where only one item is intended, the term “one” or similar language is used. For example, the term “a flip-flop” may refer to either a single flip-flop or multiple flip-flops. When a flip-flop is described as carrying out an operation and the flip-flop is referred to perform an additional operation, the multiple operations may be executed by either a single flip-flop or any one or a combination of multiple flip-flops.

Hereinafter, various embodiments of the present disclosure are described with reference to the accompanying drawings.

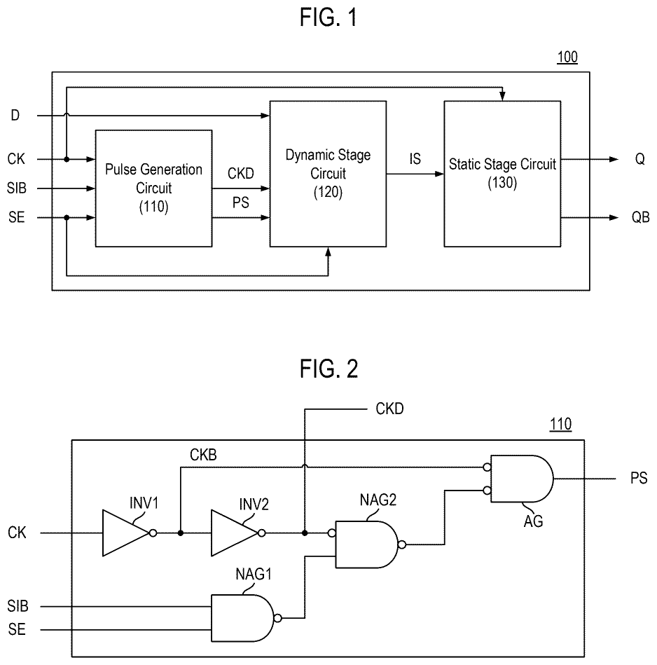

FIG. 1 is a block diagram of a scannable flip-flop, according to one or more embodiments.

Referring to FIG. 1, a scannable flip-flop 100, according to one or more embodiments, may include a pulse generation circuit 110, a dynamic stage circuit 120, and a static stage circuit 130.

The pulse generation circuit 110 may be configured to generate a delayed clock signal CKD and a pulse signal PS based on a clock signal CK, an inverted scan input signal SIB, and a scan enable signal SE.

The inverted scan input signal SIB is an inverted version of a scan input signal SI selected or used in scan mode. The inverted scan input signal SIB may be distinguished from input data D that may be used in normal mode. For the sake of brevity, an operation of the pulse generation circuit 110 is described based on the inverted scan input signal SIB, but it is to be understood that the pulse generation circuit 110 may operate based on the scan input signal SI depending on the configuration of the pulse generation circuit 110.

The scan enable signal SE may indicate the activation of scan mode. When scan mode is activated, the scan enable signal SE may be set at a first logic level (e.g., logic high). When scan mode is deactivated (e.g., normal mode is activated), the scan enable signal SE may be set at a second logic level (e.g., logic low). However, embodiments of the present disclosure are not limited thereto, and other logic levels may be used to indicate that the scan mode and/or the normal mode are activated.

The delayed clock signal CKD may be a signal delayed by a certain amount of time from the clock signal CK and/or a signal having a certain phase difference from the clock signal CK. In one or more embodiments, the pulse generation circuit 110 may generate and output the delayed clock signal CKD from the clock signal CK through an M-stage inverter chain, where M is a positive even integer greater than or equal to two (2).

The pulse signal PS may be delay-synchronized with a rising edge of the clock signal CK. As used herein, the phrase delay-synchronized with a rising edge may refer to a pulse of a certain width being generated after a certain time following the occurrence of the rising edge of the clock signal CK. For example, the pulse signal PS may transition from a logic low level to a logic high level after a certain time following the rising edge of the clock signal CK and subsequently transition back to the logic low level.

When the scan enable signal SE indicates that scan mode has been deactivated (e.g., the normal mode is activated), the pulse generation circuit 110 may output a pulse signal PS having a pulse that may be delay-synchronized with the rising edge of the clock signal CK.

When the scan enable signal SE indicates the scan mode, the pulse generation circuit 110 may output a pulse signal PS with a logic level varying depending on the inverted scan input signal SIB. The pulse generation circuit 110 may output at least one of a pulse signal PS with a pulse or a pulse signal PS with a logic low level, depending on the inverted scan input signal SIB.

The dynamic stage circuit 120 may be configured to perform operations based on the logic level of the delayed clock signal CKD. For example, when the delayed clock signal CKD is a logic high level, the dynamic stage circuit 120 may perform a precharge operation. As another example, the dynamic stage circuit 120 may transition an internal signal IS to a logic high level based on the delayed clock signal CKD.

When the delayed clock signal CKD is a logic low level, the dynamic stage circuit 120 may perform a discharge operation based on at least one of the input data D, the scan enable signal SE, or the pulse signal PS. For example, the dynamic stage circuit 120 may transition the internal signal IS to a logic low level.

The dynamic stage circuit 120 may operate according to the operation mode (e.g., the normal mode or the scan mode). In normal mode, the dynamic stage circuit 120 may operate based on the input data D. For example, when the input data D is a logic low level, the dynamic stage circuit 120 may maintain the logic level of the internal signal IS. Alternatively or additionally, when the input data D is a logic high level, the dynamic stage circuit 120 may discharge the internal signal IS.

In scan mode, the dynamic stage circuit 120 may operate based on the inverted scan input signal SIB, regardless of the input data D. For example, when a pulse is generated in the pulse signal PS based on the inverted scan input signal SIB, the dynamic stage circuit 120 may discharge the internal signal IS.

The static stage circuit 130 may be configured to, based on the clock signal CK, maintain the state of the output data Q, or to invert the internal signal IS and provide the inverted version of the internal signal IS as output data Q. In an embodiment, the static stage circuit 130 may output an inverted output data QB inverted from the output data Q.

For example, when the clock signal CK is a logic high level, the static stage circuit 130 may invert the logic level of the internal signal IS and may output the output data Q with the inverted logic level. As another example, when the clock signal CK is a logic high level, the internal signal IS may be passed to the output data Q. When the clock signal CK is a logic low level, the static stage circuit 130 may maintain or lock a current state (e.g., a current logic level) of the output data Q.

As used herein, the dynamic stage circuit 120 and the static stage circuit 130 may be referred to as semi-dynamic circuits.

The scannable flip-flop 100, according to one or more embodiments, may implement a scan multiplexing function, which may operate in a normal mode or a scan mode based on the scan enable signal SE, through the pulse generation circuit 110 and the dynamic stage circuit 120.

FIG. 2 is a circuit diagram of a pulse generation circuit 110, according to one or more embodiments.

Referring to FIG. 2, the pulse generation circuit 110 may include a first inverter INV1, a second inverter INV2, a first NAND gate NAG1, a second NAND gate NAG2, and an AND gate AG.

The first inverter INV1 may output an inverted clock signal CKB from a clock signal CK. The second inverter INV2 may be coupled in series with the first inverter INV1 and output a delayed clock signal CKD from the inverted clock signal CKB output by the first inverter INV1. The first inverter INV1 and the second inverter INV2 may form an inverter chain, and the clock signal CK may be delayed through the inverter chain. The delayed clock signal CKD may have the same phase as the clock signal CK.

The first NAND gate NAG1 may receive an inverted scan input signal SIB and a scan enable signal SE and perform a NAND operation on the inverted scan input signal SIB and the scan enable signal SE.

The second NAND gate NAG2 may receive an inversion of the delayed clock signal CKD output from the second inverter INV2 and an output of the first NAND gate NAG1, and perform a NAND operation on the inversion of the delayed clock signal CKD and the output of the first NAND gate NAG1. A terminal of the second NAND gate NAG2 receiving the delayed clock signal CKD may be an inverting terminal.

The AND gate may receive an inversion of the inverted clock signal CKB and an inversion of the output of the second NAND gate NAG2, and perform an AND operation on the inversion of the inverted clock signal CKB and the inversion of the output of the second NAND gate NAG2. Both input terminals of the AND gate AG may be inverting terminals. The output of the AND gate AG may be a pulse signal PS.

Hereinafter, the operation of the pulse generation circuit 110 is described with reference to FIG. 2.

When the scan enable signal SE indicates the normal mode, the output of the first NAND gate NAG1 may always be a logic high. Consequently, the output of the second NAND gate NAG2 may have the same logic level as the delayed clock signal CKD. During a period in which both the inversion of the inverted clock signal CKB and the inversion of the output of the second NAND gate NAG2 are a logic high level, the pulse signal PS may have a pulse.

When the scan enable signal SE indicates the scan mode, the pulse signal PS may be output based on the logic level of the inverted scan input signal SIB. When the inverted scan input signal SIB is a logic low level (e.g., the scan input signal is a logic high level), the pulse signal PS may be defined as an AND operation of the clock signal CK and the inversion of the delayed clock signal CKD. Accordingly, the pulse signal PS may be output the same as in normal mode. When the inverted scan input signal SIB is a logic high level, the pulse signal PS may indicate a logic low level. For example, a pulse may not be generated.

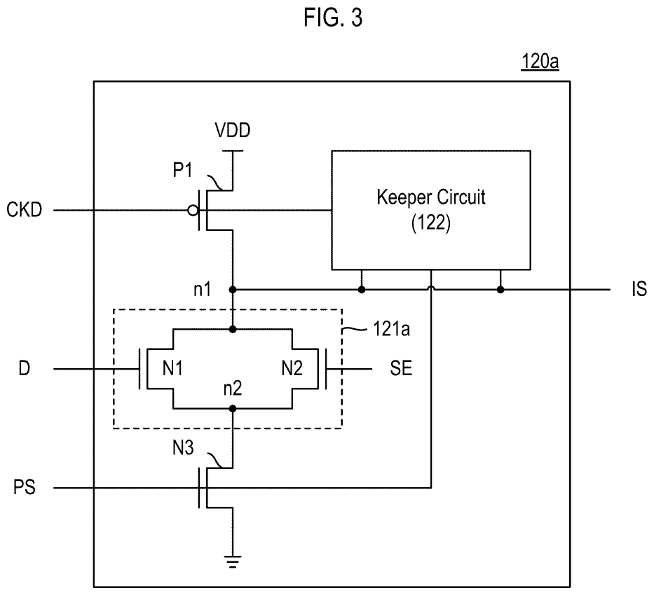

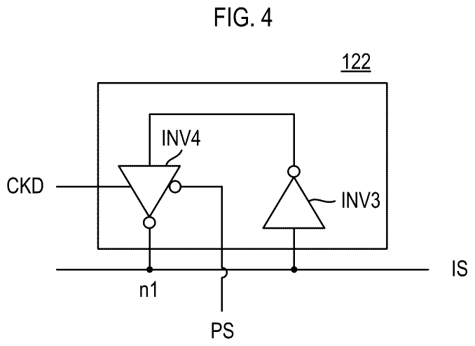

FIG. 3 is a circuit diagram of a dynamic stage circuit, according to one or more embodiments. FIG. 4 is a circuit diagram of a keeper circuit, according to one or more embodiments.

Referring to FIGS. 3 and 4, a dynamic stage circuit 120a, according to one or more embodiments, may include a first P-type transistor P1, a path formation circuit 121a, a third N-type transistor N3, and a keeper circuit 122.

The first P-type transistor P1 may include a source provided with a power supply voltage VDD, a gate provided with a delayed clock signal CKD, and a drain coupled with a first node n1. The first P-type transistor P1 may precharge the first node n1 based on the delayed clock signal CKD. For example, when the delayed clock signal CKD is a logic high level, the first P-type transistor P1 may be turned on and the first node n1 may be precharged to the power supply voltage VDD.

The path formation circuit 121a may be coupled with the first node n1 and a second node n2 and may be configured to provide a path between the first node n1 and the second node n2. As shown in FIG. 2, the path formation circuit 121a, according to one or more embodiments, may include a first N-type transistor N1 and a second N-type transistor N2 coupled in parallel between the first node n1 and the second node n2.

The first N-type transistor N1 may include a drain coupled with the first node n1, a gate provided with input data D, and a source coupled with the second node n2. The second N-type transistor N2 may be coupled in parallel with the first N-type transistor N1 and include a drain coupled with the first node n1, a gate provided with a scan enable signal SE, and a source coupled with the second node n2.

The first N-type transistor N1 may be turned on based on the input data D. For example, when the input data D is a logic high level, the first N-type transistor N1 may be turned on. The second N-type transistor N2 may be turned on based on the scan enable signal SE. For example, when the scan enable signal SE is a logic high level (e.g., when the scan mode is activated), the second N-type transistor N2 may be turned on. When at least one of the first N-type transistor N1 or the second N-type transistor N2 is turned on, a path may be formed between the first node n1 and the second node n2.

When a path is not formed between the first node n1 and the second node n2, a voltage at the first node n1 may be floated or precharged.

The third N-type transistor N3 may include a drain coupled with the second node n2, a gate provided with a pulse signal PS, and a grounded source. The third N-type transistor N3 may discharge the first node n1 based on the pulse signal PS. For example, when a path is formed between the first node n1 and the second node n2 through the path formation circuit 121a and the pulse signal PS is logic high (e.g., when a pulse is generated), the third N-type transistor N3 may be turned on to discharge the first node n1 to the ground voltage.

According to one or more embodiments, the first node n1 may precharged, floated, or discharged, and a voltage level of the first node n1 may be output as an internal signal IS.

The keeper circuit 122 may be configured to maintain the voltage level of the first node n1 (e.g., the logic level of the internal signal IS).

In some embodiments, the keeper circuit 122 may include a third inverter INV3 and a fourth inverter INV4. The third inverter INV3 may receive the voltage of the first node n1 and invert the voltage of the first node n1. The fourth inverter INV4 may be coupled with the third inverter INV3 in a back-to-back manner. The fourth inverter INV4 may reinvert the inverted voltage of the first node n1 and output reinverted voltage to the first node n1.

However, embodiments of the present disclosure are not limited thereto, and the keeper circuit 122 may be variously configured to maintain the voltage level of the first node n1.

In some embodiments, the fourth inverter INV4 may be configured as a tri-state inverter activated based on at least one of the delayed clock signal CKD or the pulse signal PS. For example, the delayed clock signal CKD and the inverted signal of the pulse signal PS may be provided to the fourth inverter INV4 to indicate whether the inverting operation is activated. When a pulse is generated in the pulse signal PS (e.g., when the inverted signal of the pulse signal PS is a logic low level), the fourth inverter INV4 may not maintain the voltage at the first node n1 to pass the internal signal IS.

According to one or more embodiments, the dynamic stage circuit 120a may couple the second N-type transistor N2, may be configured to turn on and/or off based on the scan enable signal SE, and may be coupled in parallel with the first N-type transistor N1, thereby enabling the scannable flip-flop to operate based on scan multiplexing while maintaining a two-stage stack structure of the first N-type transistor N1 and the third N-type transistor N3.

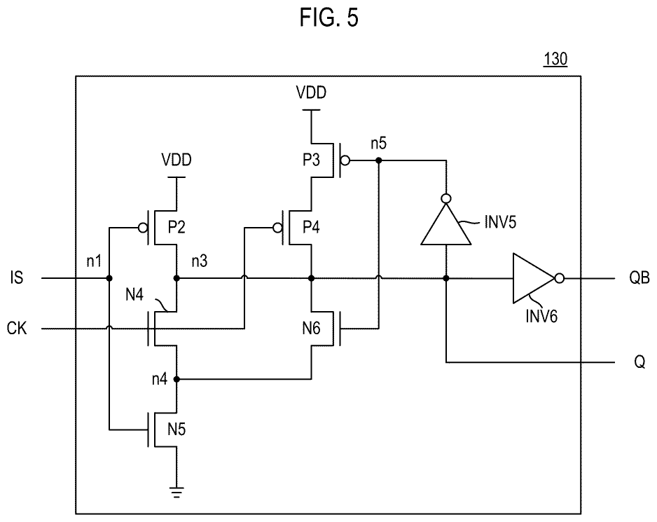

FIG. 5 is a circuit diagram of a static stage circuit, according to one or more embodiments.

Referring to FIG. 5, a static stage circuit 130, according to one or more embodiments, may include a second P-type transistor P2, a fourth N-type transistor N4, a fifth N-type transistor N5, a fifth inverter INV5, a third P-type transistor P3, a fourth P-type transistor P4, a sixth N-type transistor N6, and a sixth inverter INV6.

The second P-type transistor P2 may include a source provided with a power supply voltage VDD, a gate coupled with a first node n1, and a drain coupled with a third node n3. The second P-type transistor P2 may precharge the third node n3, at which output data Q is output, based on a voltage level of the first node n1 (e.g., a logic level of an internal signal IS). For example, when the internal signal IS is a logic low level, the second P-type transistor P2 may be turned on to precharge the third node n3.

The fourth N-type transistor N4 may include a drain coupled with the third node n3, a gate provided with a clock signal CK, and a source coupled with a fourth node n4. The fourth N-type transistor N4 may be turned on based on the clock signal CK. For example, when the clock signal CK is a logic high level, the fourth N-type transistor N4 may be turned on to provide a path between the third node n3 and the fourth node n4.

The fifth N-type transistor N5 may include a drain coupled with the fourth node n4, a gate coupled with the first node n1, and a grounded source. The fifth N-type transistor N5 may discharge the third node n3 based on the voltage level of the first node n1 (e.g., the logic level of the internal signal IS). For example, when the fourth N-type transistor N4 is turned on and the internal signal IS is a logic high level, the fifth N-type transistor N5 may be turned on to discharge the third node n3.

The fifth inverter INV5 may receive and invert a voltage at the third node n3, and output the inverted voltage to a fifth node n5.

The third P-type transistor P3 may include a source provided with a power supply voltage VDD, a gate coupled with the fifth node n5, and a drain coupled with the source of the fourth P-type transistor P4. The third P-type transistor P3 may precharge the third node n3 based on the output of the fifth inverter INV5. For example, when the fourth P-type transistor P4 is turned on and the output of the fifth inverter INV5 is a logic low level, the third P-type transistor P3 may be turned on to precharge the third node n3.

The fourth P-type transistor P4 may include a source coupled with the drain of the third P-type transistor P3, a gate provided with the clock signal CK, and a drain coupled with the third node n3. The fourth P-type transistor P4 may be turned on based on the clock signal CK. For example, when the clock signal CK is a logic low level, the fourth P-type transistor P4 may be turned on to provide a path between the third P-type transistor P3 and the third node n3.

The sixth N-type transistor N6 may include a drain coupled with the third node n3, a gate coupled with the fifth node n5, and a source coupled with the fourth node n4. The sixth N-type transistor N6 may be turned on based on the output of the fifth inverter INV5. For example, when the output of the fifth inverter INV5 is a logic high level, the sixth N-type transistor N6 may be turned on to provide a path between the third node n3 and the fourth node n4.

The third P-type transistor P3, the fourth P-type transistor P4, the fifth N-type transistor N5, and the sixth N-type transistor N6, according to one or more embodiments, may form a tri-state inverter that may operate based on the internal signal IS and the clock signal CK. The fifth inverter INV5 may form a keeper circuit along with the tri-state inverter. Thus, the voltage level of the third node n3 may be maintained when the keeper circuit is activated.

According to one or more embodiments, the third node n3 may be precharged, floated, or discharged, and the voltage level of the third node n3 may be output as output data Q.

The sixth inverter INV6 may be coupled with the third node n3 and output inverted output data QB inverted from the output data Q.

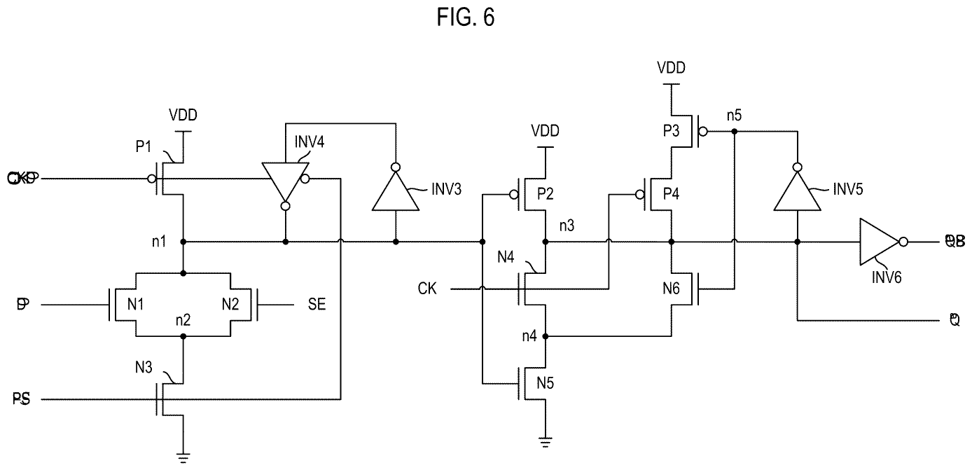

FIG. 6 is a circuit diagram illustrating a combination of the dynamic stage circuit of FIG. 3 and the static stage circuit of FIG. 5. Hereafter, detailed descriptions of elements of the circuit diagram shown in FIG. 6 that may be substantially similar and/or the same as elements described above with reference to FIGS. 3 and 5 may be omitted for the sake of brevity.

Referring to FIG. 6, the dynamic stage circuit and the static stage circuit may operate in normal mode and/or scan mode based on the scan enable signal SE.

### Normal Mode

When the scan enable signal SE is a logic low level, the second N-type transistor N2 may be turned off. Thus, the path formation between the first node n1 and the second node n2 may depend on the input data D. When the input data D is a logic low level, the first node n1 and the second node n2 may be floated regardless of the pulse signal PS.

When the delayed clock signal CKD is a logic low level, the first P-type transistor P1 may be turned on. Thus, the first node n1 may be precharged. When the clock signal CK is a logic low level, the discharge path for the third node n3 in the static stage circuit may be blocked. As a result, the logic level of the output data Q may be maintained at the logic level of the previous state.

When the clock signal CK is a logic high level, a discharge path for the third node n3 may be formed to discharge the third node n3. Accordingly, the input data D corresponding to a logic low level may be passed to the output data Q (or the output data Q may be sampled at the logic level of the input data D).

When the delayed clock signal CKD is a logic high level, the first P-type transistor P1 may be turned off. In a case in which a pulse is generated in the pulse signal PS (e.g., the logic level of the pulse signal PS transitions from a logic low level to a logic high level and then back to the logic low level), the third N-type transistor N3 may be turned on when the pulse signal PS is a logic high level. However, a discharge path may not be formed for the first node n1 when the input data D is a logic low level. Therefore, the voltage level of the first node n1 may be maintained.

When the input data D is a logic high level, a discharge path for the first node n1 may be formed during a turn-on period of the third N-type transistor N3. When the first node n1 is discharged, the second P-type transistor P2 in the static stage circuit may be turned on. Accordingly, the third node n3 may be precharged. As a result, the input data D corresponding to a logic high level may be passed to the output data Q (or the output data Q may be sampled at the logic level of the input data D).

### Scan Mode

In the scan mode, the second N-type transistor N2 may always be turned on. The formation of the discharge path may depend on the third N-type transistor N3. As described above, the pulse signal PS may indicate a logic low level when the scan input signal is a logic low level in scan mode. Accordingly, the third N-type transistor N3 may be turned off, and the discharge path for the first node n1 may be blocked. When the delayed clock signal CKD is a logic high level, the first node n1 may be precharged. The fifth N-type transistor N5 may be turned on, and a discharge path for the third node n3 may be formed depending on the logic level of the clock signal CK. As a result, a logic-low scan input signal may be passed to the output data Q.

The pulse signal PS may have a pulse when the scan input signal is a logic high level in scan mode. When a pulse is generated, a discharge path for the first node n1 may be formed. Therefore, the second P-type transistor P2 may be turned on. As a result, the third node n3 may be precharged, and a logic-high scan input signal may be passed to the output data Q.

The dynamic stage circuit and the static stage circuit, according to one or more embodiments, may enable the scannable flip-flop to operate based on scan multiplexing while maintaining the two-stage stack structure of the first N-type transistor N1 and the third N-type transistor N3.

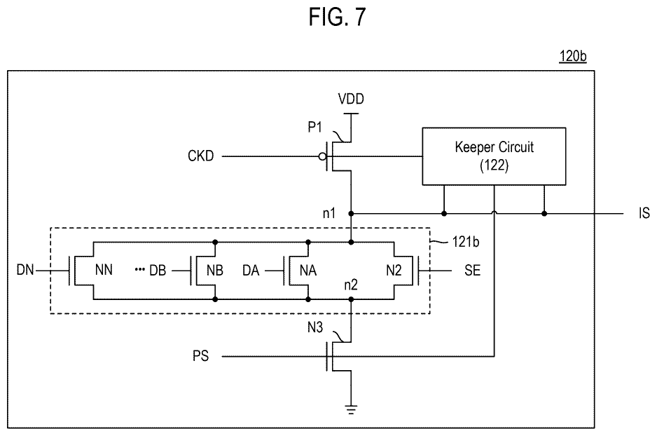

FIG. 7 is a circuit diagram of a dynamic stage circuit 120b implementing a logic wide-OR circuit, according to one or more embodiments.

Referring to FIG. 7, a path formation circuit may include a plurality of N-type transistors (e.g., a first N-type transistor NA, a second N-type transistor NB, to an N-th N-type transistor NN, where N is a positive integer greater than one (1)) coupled in parallel with a second N-type transistor N2. For example, in addition to the first N-type transistor NA, according to one or more embodiments, one or more N-type transistors NB to NN coupled in parallel with the first N-type transistor NA may be further included in the path formation circuit 121b. In some embodiments, only the first N-type transistor NA, the second N-type transistor N2, and a single N-type transistor NB may be included in the path formation circuit.

The plurality of N-type transistors NA to NN may be turned on based on first to N-th input data DA to DN. The plurality of N-type transistors NA to NN connected in parallel between the first node n1 and the second node n2 may implement a logic wide-OR circuit. In the normal mode, when at least one of the first to N-th input data DA to DN is a logic high level and the third N-type transistor N3 is turned on, a discharge path for the first node n1 may be formed. The output data Q indicates a logic high level, so that the logic wide-OR circuit for the input data DA to DN may be implemented.

The first P-type transistor P1 may precharge the first node n1 based on the delayed clock signal CKD, regardless of the plurality of N-type transistors NA to NN. The keeper circuit 122 may be activated based on a delayed clock signal CKD and a pulse signal PS to maintain a voltage level of a first node n1.

The dynamic stage circuit 120b, according to one or more embodiments, may implement a logic wide-OR circuit while maintaining a two-stage stack.

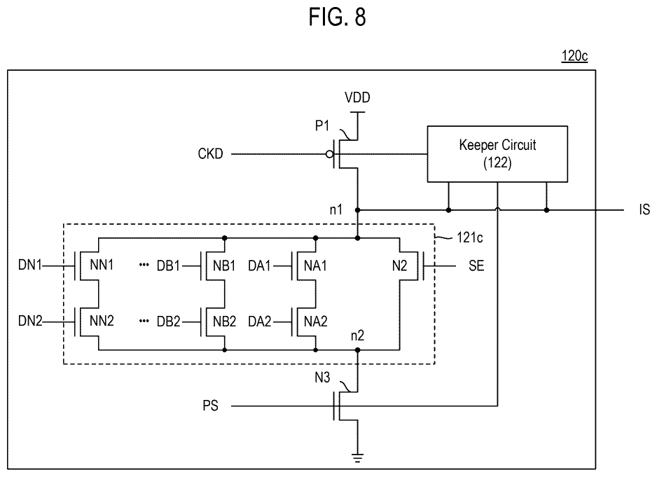

FIG. 8 is a circuit diagram of a dynamic stage circuit implementing a logic wide-OR circuit and a logic AND circuit, according to one or more embodiments.

Referring to FIG. 8, a path formation circuit 121c included in the dynamic stage circuit 120c, according to one or more embodiments, may include a plurality of first stack transistors (e.g., a first stack transistor NA1, a second stack transistor NB1, to an N-th stack transistor NN1) and a plurality of second stack transistors (e.g., a first stack transistor NA2, a second stack transistor NB2, to an N-th stack transistor NN2) between a first node n1 and a second node n2. The plurality of second stack transistors NA2 to NN2 may be stacked on the plurality of first stack transistors NA1 to NN1.

The plurality of first stack transistors NA1 to NN1 may be turned on based on first to N-th first input data DA1 to DN1, and the plurality of second stack transistors NA2 to NN2 may be turned on based on first to N-th second input data DA2 to DN2.

Two (2) transistors stacked between the first node n1 and the second node n2 (or two (2) transistors connected in a cascode structure) may implement a logic AND circuit. In addition, transistors connected in parallel between the first node n1 and the second node n2 may implement a logic wide-OR circuit as described above.

Accordingly, the path formation circuit 121c of FIG. 8 may implement the logic {(DA1 AND DA2) OR (DB1 AND DB2) OR ( . . . ) OR (DN1 AND DN2)}. The number of OR operations may increase depending on stacked transistors added between stacked transistors NB1 and NB2 and stacked transistors NN1 and NN2. In some embodiments, only one set of stacked transistors (e.g., NA1 and NA2) and the second N-type transistor N2 may be included in the path formation circuit 121c.

The first P-type transistor P1 may precharge the first node n1 based on a delayed clock signal CKD, regardless of the plurality of first stack transistors NA1 to NN1 and the plurality of second stack transistors NA2 to NN2. The keeper circuit 122 may be activated based on the delayed clock signal CKD and the pulse signal PS to maintain the voltage level of the first node n1. A discharge path for the first node n1 may be formed based on the logic of the path formation circuit 121c and whether the third N-type transistor N3 is turned on.

The dynamic stage circuit 120c, according to one or more embodiments, may implement a logic wide-OR circuit and a logic AND circuit while maintaining a two-stage stack.

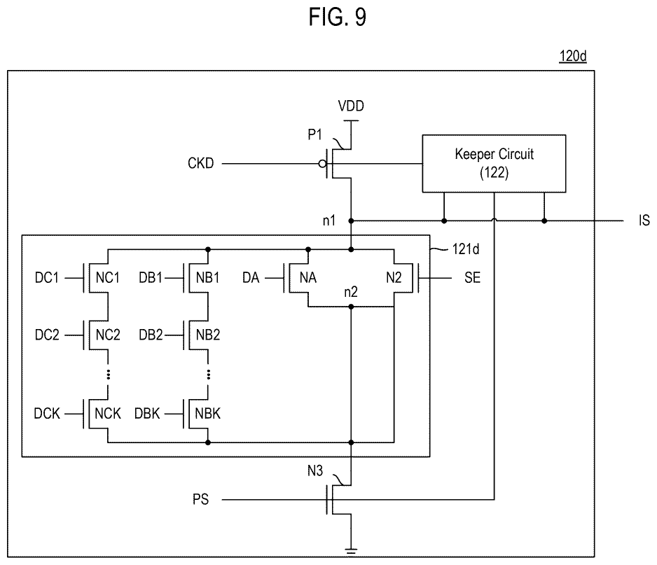

FIG. 9 is a circuit diagram of a dynamic stage circuit implementing a logic wide-OR circuit and a logic AND circuit, according to one or more embodiments.

Referring to FIG. 9, a path formation circuit 121d included in the dynamic stage circuit 120d, according to one or more embodiments, may further include stack transistors (e.g., a first stack transistor NB2 to a K-th stack transistor NBK, where K is a positive integer greater than one (1)) and (e.g., a first stack transistor NC2 to a K-th stack transistor NCK), sequentially stacked on a plurality of second stack transistors NB2 to NC2, in addition to the plurality of first stack transistors NA to NC1 and the plurality of second stack transistors NB2 to NC2 between the first node n1 and the second node n2. The path formation circuit 121d in FIG. 9 may implement the logic {(DA1 OR (DB1 AND DB2 AND ( . . . ) AND DBK) OR (DN1 AND DN2 AND ( . . . ) DCK)}. The number of AND operations may increase depending on stacked transistors added between the stacked transistors NB2 and NC2 and the stacked transistors NBK and NCK.

A first P-type transistor P1 may precharge a first node n1 based on a delayed clock signal CKD, regardless of transistors included in a path formation circuit 121d. The keeper circuit 122 may be activated based on the delayed clock signal CKD and the pulse signal PS to maintain the voltage level of the first node n1. A discharge path for the first node n1 may be formed based on the logic of a path formation circuit 121d and whether a third N-type transistor N3 is turned on.

The dynamic stage circuit 120d, according to one or more embodiments, may implement a logic wide-OR circuit and a logic AND circuit while maintaining a two-stage stack.

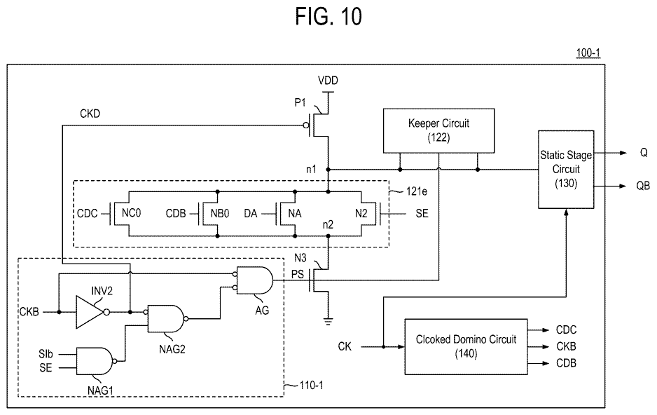

FIG. 10 is a circuit diagram of a scannable flip-flop including a clocked domino circuit, according to one or more embodiments.

Referring to FIG. 10, a scannable flip-flop circuit 100-1, according to one or more embodiments, may include a logic circuit 110-1, a dynamic stage circuit, a static stage circuit 130, and a clocked domino circuit 140.

The logic circuit 110-1 may be included in the pulse generation circuit 110, according to one or more embodiments. The logic circuit 110-1 may include a second inverter INV2, a first NAND gate NAG1, a second NAND gate NAG2, and an AND gate AG. The logic circuit 110-1 may generate a pulse signal PS and may output the pulse signal PS to a gate of a third N-type transistor N3.

The dynamic stage circuit may include a first P-type transistor P1, a path formation circuit 121e, a third N-type transistor N3, and a keeper circuit 122. The path formation circuit 121e may include a first N-type transistor NA and one or more transistors NB0 and NC0 coupled in parallel with a second N-type transistor N2. The one or more transistors NB0 and NC0 are not limited to the illustration of FIG. 10 and may further include one (1) or three (3) or more transistors.

The one or more transistors NB0 and NC0 may be turned on based on common drain signals CDB and CDC.

The static stage circuit 130 may output the output data Q and the inverted output data QB, according to one or more embodiments.

The clocked domino circuit 140 may be configured to output the common drain signals CDB and CDC based on a clock signal CK.

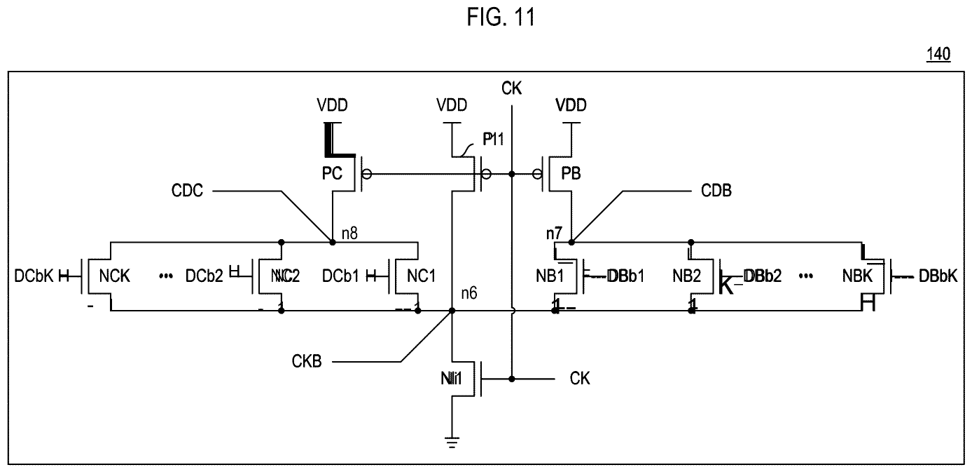

FIG. 11 is a circuit diagram of the clocked domino circuit of FIG. 10.

Referring to FIG. 11, the clocked domino circuit 140, according to one or more embodiments, may include a P-type transistor PI1 and an N-type transistor NI1. The P-type transistor PI1 may include a source provided with a power supply voltage VDD, a gate provided with a clock signal CK, and a drain coupled with a sixth node n6. The P-type transistor PI1 may be coupled with a sixth node n6 and precharge the sixth node n6 based on a clock signal CK. The N-type transistor NI1 may include a drain coupled with the sixth node n6, a gate provided with the clock signal CK, and a grounded source. The N-type transistor NI1 may be coupled with the sixth node n6 and discharge the sixth node n6 based on the clock signal CK. The above-described clock inversion signal may be output by precharging and discharging the sixth node n6.

The P-type transistor PI1 and the N-type transistor NI1 may correspond to the first inverter included in the above-described pulse generation circuit of FIG. 2.

In some embodiments, the clocked domino circuit 140 may include a P-type transistor PB and a plurality of N-type transistors NB1 to NBK. The P-type transistor PB may include a source provided with a power supply voltage VDD, a gate provided with a clock signal CK, and a drain coupled with a seventh node n7. The P-type transistor PB may precharge the seventh node n7, at which a common drain signal is output, based on the clock signal CK.

The plurality of N-type transistors NB1 to NBK are coupled in parallel between the sixth node n6 and the seventh node n7. The plurality of N-type transistors NB1 to NBK may be turned on based on inverted input data DBb1 to DBbK. The inverted input data DBb1 to DBbK may be inverted from the input data DB1 to DBK. When the inverted input data DBb1 to DBbK are all a logic low level (e.g., when the input data DB1 to DBK are all a logic high level), a path between the sixth node n6 and the seventh node n7 may be floated. Thus, the voltage level of the common drain signal CDB output by the seventh node n7 may be maintained at a logic high level.

In some embodiments, the clocked domino circuit 140 may include a P-type transistor PC and a plurality of N-type transistors NC1 to NCK. The P-type transistor PC may include a source provided with the power supply voltage VDD, a gate provided with the clock signal CK, and a drain coupled with an eighth node n8. The P-type transistor PC may precharge the eighth node n8, at which a common drain signal is output, based on the clock signal CK.

The plurality of N-type transistors NC1 to NCK may be coupled in parallel between the sixth node n6 and the eighth node n8. The plurality of N-type transistors NC1 to NCK may be turned on based on inverted input data DCb1 to DCbK. The inverted input data DCb1 to DCbK may be inverted from the input data DC1 to DCK. When the inverted input data DCb1 to DCbK are all a logic low level (e.g., when the input data DC1 to DCK are all a logic high level, a path between the sixth node n6 and the eighth node n8 may be floated. Thus, the voltage level of the common drain signal CDC output by the eighth node n8 may be maintained at a logic high level.

When the common drain signals CDB and CDC indicate a logic high level, one or more transistors NB0 and NC0 of FIG. 10 may be turned on. As a result, the clocked domino circuit 140 may implement the logic {(DA1 OR (DB1 AND DB2 AND ( . . . ) AND DBK) OR (DN1 AND DN2 AND ( . . . ) DCK)}, as shown on FIG. 9.

The scannable flip-flop, according to one or more embodiments, may implement a wide-OR operation and an AND operation using only transistors in a wide-OR structure, so that the use of stacked transistors may be significantly reduced.

As described above, the operations of the dynamic stage circuit and/or the static stage circuit based on (or related to) the clock signal CK, according to one or more embodiments, may be performed based on the delayed clock signal CKD, and the operations of the dynamic stage circuit and/or the static stage circuit based on (or related to) the delayed clock signal CKD may be performed based on the clock signal CK. For example, the delayed clock signal CKD applied to the dynamic stage circuit, according to one or more embodiments, may be replaced with the clock signal CK, and/or the clock signal CK applied to the static stage circuit may be replaced with the delayed clock signal CKD.

As set forth above, according to one or more embodiments, a scannable flip-flop providing a scan multiplexing function while significantly reducing a delay may be provided.

While various embodiments have been shown and described above, it is to be apparent to those skilled in the art that modifications and variations may be made without departing from the scope of the present disclosure as defined by the appended claims.

What is claimed is:

1. A flip-flop comprising:
a pulse generation circuit configured to:
output a delayed clock signal, and
output a pulse signal that is delay-synchronized with a rising edge of a clock signal based on the clock signal, an inverted scan input signal, and a scan enable signal, the scan enable signal indicating activation of a scan mode;
a dynamic stage circuit comprising:
a first P-type transistor configured to precharge a first node based on the delayed clock signal;
a first N-type transistor coupled with the first node and a second node and configured to turn on based on input data;
a second N-type transistor coupled in parallel with the first N-type transistor and configured to turn on based on the scan enable signal; and
a third N-type transistor coupled with the second node and configured to discharge the first node based on the pulse signal; and
a static stage circuit configured to:
based on the clock signal being a first logic level, invert a voltage at the first node and provide the inverted voltage as output data, and
based on the clock signal being a second logic level, maintain a state of the output data.

2. The flip-flop of claim 1, wherein the pulse generation circuit is further configured to:
output the pulse signal delay-synchronized with the rising edge of the clock signal based on the scan enable signal indicating a normal mode; and
output the pulse signal having a logic level varying based on the inverted scan input signal based on the scan enable signal indicating the scan mode.

3. The flip-flop of claim 1, wherein the pulse generation circuit comprises:
a first inverter configured to:
invert the clock signal, and
output the inverted clock signal;
a second inverter configured to output the delayed clock signal based on the inverted clock signal;
a first NAND gate configured to receive the inverted scan input signal and the scan enable signal;
a second NAND gate configured to receive an inversion of the delayed clock signal and an output of the first NAND gate; and
an AND gate configured to receive an inversion of the inverted clock signal and an inversion of an output of the second NAND gate.

4. The flip-flop of claim 1, wherein the dynamic stage circuit further comprises a keeper circuit configured to maintain a voltage level of the first node, and
wherein the keeper circuit comprises:
a third inverter configured to receive the voltage at the first node; and
a fourth inverter coupled with the third inverter in a back-to-back manner.

5. The flip-flop of claim 4, wherein the fourth inverter comprises a tri-state inverter activated based on at least one of the delayed clock signal or the pulse signal.

6. The flip-flop of claim 1, wherein the static stage circuit comprises:
a second P-type transistor configured to precharge a third node, at which the output data is output, based on a voltage level of the first node;
a fourth N-type transistor coupled with the third node and a fourth node and configured to turn on based on the clock signal;
a fifth N-type transistor coupled with the fourth node and configured to discharge the third node based on the voltage level of the first node;
a fifth inverter configured to receive a voltage at the third node;
a third P-type transistor configured to receive an output of the fifth inverter through a fifth node and precharge the third node based on the output of the fifth inverter;
a fourth P-type transistor coupled with the third P-type transistor and the third node and configured to turn on based on the clock signal;
a sixth N-type transistor coupled with the third node and the fourth node, and configured to:
receive the output of the fifth inverter through the fifth node, and
turn on based on the output of the fifth inverter; and
a sixth inverter coupled with the third node and configured to:
invert the output data, and
output the inverted output data.

7. The flip-flop of claim 1, wherein the dynamic stage circuit further comprises:
one or more seventh N-type transistors coupled in parallel with the first N-type transistor and configured to turn on based on the input data.

8. The flip-flop of claim 7, wherein the dynamic stage circuit further comprises:
one or more eighth N-type transistors stacked on the one or more seventh N-type transistors and configured to turn on based on the input data.

9. The flip-flop of claim 3, wherein the first inverter comprises:
a fifth P-type transistor configured to precharge a sixth node based on the clock signal; and
a ninth N-type transistor configured to discharge the sixth node based on the clock signal.

10. The flip-flop of claim 9, wherein the dynamic stage circuit further comprises:
one or more ninth N-type transistors coupled in parallel to the first N-type transistor and configured to turn on based on a common drain signal.

11. The flip-flop of claim 10, further comprising:
a clocked domino circuit configured to output the common drain signal based on the clock signal,
wherein the clocked domino circuit comprises:
a sixth P-type transistor configured to precharge a seventh node, at which the common drain signal is output, based on the clock signal; and
a plurality of tenth N-type transistors coupled with the sixth node and the seventh node and configured to turn on based on inverted input data inverted from the input data.

12. A flip-flop comprising:
a pulse generation circuit configured to:
output a delayed clock signal, and
output a pulse signal that is delay-synchronized with a rising edge of a clock signal based on the clock signal, an inverted scan input signal, and a scan enable signal, the scan enable signal indicating activation of a scan mode;
a dynamic stage circuit configured to:
output an internal signal,
transition the internal signal to a logic high level based on the delayed clock signal, and
transition the internal signal to a logic low level based on at least one of input data, the scan enable signal, or the pulse signal; and
a static stage circuit configured to:
based on the clock signal being a first logic level, invert a voltage at a first node and provide the inverted voltage as output data, and
based on the clock signal being a second logic level, maintain a state of the output data.

13. The flip-flop of claim 12, wherein the pulse generation circuit comprises:
a first inverter configured to:
invert the clock signal, and
output the inverted clock signal;
a second inverter configured to output the delayed clock signal based on the inverted clock signal;
a first NAND gate configured to receive the inverted scan input signal and the scan enable signal;
a second NAND gate configured to receive an inversion of the delayed clock signal and an output of the first NAND gate; and
an AND gate configured to receive an inversion of the inverted clock signal and an inversion of an output of the second NAND gate.

14. The flip-flop of claim 12, wherein the dynamic stage circuit comprises:
a first P-type transistor configured to precharge the first node, at which the internal signal is output, based on the delayed clock signal;
a first N-type transistor coupled with the first node and a second node and configured to turn on based on the input data;
a second N-type transistor coupled in parallel with the first N-type transistor and configured to turn on based on the scan enable signal; and
a third N-type transistor coupled with the second node and configured to discharge the first node based on the pulse signal.

15. The flip-flop of claim 14, wherein the dynamic stage circuit further comprises a keeper circuit configured to maintain a voltage level of the first node, and
wherein the keeper circuit comprises:
a third inverter configured to receive the voltage at the first node; and
a fourth inverter coupled with the third inverter in a back-to-back manner.

16. The flip-flop of claim 14, wherein the dynamic stage circuit further comprises:
one or more second N-type transistors coupled in parallel with the first N-type transistor and configured to turn on based on the input data.

17. The flip-flop of claim 16, wherein the dynamic stage circuit further comprises:
one or more third N-type transistors stacked on the one or more second N-type transistors and configured to turn on based on the input data.

18. A flip-flop comprising:
a pulse generation circuit configured to:
output a delayed clock signal, and
output a pulse signal that is delay-synchronized with a rising edge of a clock signal based on the clock signal, an inverted scan input signal, and a scan enable signal, the scan enable signal indicating activation of a scan mode;
a dynamic stage circuit comprising:
a first P-type transistor configured to precharge a first node based on the delayed clock signal;
a path formation circuit coupled with the first node and a second node and configured to provide a path between the first node and the second node based on at least one of input data or the scan enable signal; and
a first N-type transistor coupled with the second node and configured to discharge the first node based on the pulse signal; and
a static stage circuit configured to:
based on the clock signal being a first logic level, invert a voltage at the first node and provide the inverted voltage as output data, and
based on the clock signal being a second logic level, maintain a state of the output data.

19. The flip-flop of claim 18, wherein the path formation circuit comprises:
a second N-type transistor coupled with the first node and the second node and configured to turn on based on the input data; and
a third N-type transistor coupled in parallel with the second N-type transistor and configured to turn on based on the scan enable signal.

20. The flip-flop of claim 18, wherein the pulse generation circuit comprises:
a first inverter configured to:
invert the clock signal, and
output the inverted clock signal;
a second inverter configured to output the delayed clock signal based on the inverted clock signal;
a first NAND gate configured to receive the inverted scan input signal and the scan enable signal;
a second NAND gate configured to receive an inversion of the delayed clock signal and an output of the first NAND gate; and
an AND gate configured to receive an inversion of the inverted clock signal and an inversion of an output of the second NAND gate.
